(19) United States
(12) Patent Application Publication
(10) Pub. No.: US 2024/0090240 A1
(43) Pub. Date: Mar. 14, 2024

(54) INTEGRATED CIRCUIT DEVICE

(71) Applicant: Samsung Electronics Co., Ltd., Suwon-si (KR)

(72) Inventors: TAKUYA FUTATSUYAMA, Suwon-si (KR); Daeseok Byeon, Suwon-si (KR); Gyosoo Choo, Suwon-si (KR)

(73) Assignee: Samsung Electronics Co., Ltd., Suwon-si (KR)

(21) Appl. No.: 18/367,704

(22) Filed: Sep. 13, 2023

(30) Foreign Application Priority Data
Sep. 14, 2022 (KR) 10-2022-0115805

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2924/1431; H01L 2924/14511

(57) ABSTRACT

An integrated circuit (IC) device includes a peripheral circuit structure and cell array structure. The peripheral circuit structure includes a circuit substrate, a peripheral circuit, a first insulating layer covering the circuit substrate and the peripheral circuit, and a first bonding pad. The cell array structure includes an insulating structure having first and second surfaces opposing each other, a conductive plate on the first surface, a memory cell array on the conductive plate, a second insulating layer, a second bonding pad disposed on the second insulating layer, first and second wiring lines spaced apart from each other on the second surface, a conductive via passing through the insulating structure and connecting the conductive plate to the first wiring line, and a contact structure electrically connecting the first wiring line to the second bonding pad. The first bonding pad is in contact with the second bonding pad.

### CROSS-REFERENCE TO RELATED APPLICATION

This application is based on and claims priority from 35 U.S.C. § 119 to Korean Patent Application No. 10-2022-0115805, filed on Sep. 14, 2022, in the Korean Intellectual Property Office, the disclosure of which is incorporated by reference herein in its entirety.

### BACKGROUND

The present disclosure relates to an integrated circuit (IC) device, and more particularly, to an IC device having a non-volatile vertical memory device.

In order to satisfy the requirements for excellent performance and economic feasibility, it is required to increase the degree of integration of IC devices. In particular, the degree of integration of memory devices is an important factor in determining the economic feasibility of products. Because the degree of integration of 2D memory devices is mainly determined by the area occupied by a unit memory cell, the degree of integration is significantly affected by the level of fine pattern formation technology. However, because expensive equipment is required to form fine patterns and the area of chip dies is limited, the degree of integration of 2D memory devices has increased but is still limited. Therefore, a vertical memory device having a three-dimensional structure is required.

### SUMMARY

It is an aspect to provide an integrated circuit (IC) device in which a through-wiring line placement region in a memory cell is further secured by disposing a wiring line connecting a common source line (CSL) to a CSL driver at an outer portion of the common source line in a vertical memory device, thereby increasing the degree of integration.

According to an aspect of one or more embodiments, there is provided an integrated circuit (IC) device comprising a peripheral circuit structure and cell array structure. The peripheral circuit structure comprises a circuit substrate; a peripheral circuit on the circuit substrate; a first insulating layer covering the circuit substrate and the peripheral circuit; and a first bonding pad disposed on the first insulating layer. The cell array structure comprises an insulating structure having a first surface and a second surface opposing the first surface; a conductive plate on the first surface of the insulating structure; a memory cell array on the conductive plate; a second insulating layer covering the first surface of the insulating structure, the conductive plate, and the memory cell array; a second bonding pad disposed on the second insulating layer; a first wiring line and a second wiring line spaced apart from each other on the second surface of the insulating structure; a conductive via passing through the insulating structure and connecting the conductive plate to the first wiring line; and a contact structure electrically connecting the first wiring line to the second bonding pad. The first bonding pad is in contact with the second bonding pad.

According to another aspect of one or more embodiments, there is provided an integrated circuit (IC) including a peripheral circuit structure including a circuit substrate, a peripheral circuit on the circuit substrate, a first insulating layer covering the peripheral circuit, and a first bonding pad disposed on the first insulating layer, a first cell array structure including a first conductive plate, a first memory cell array below the first conductive plate, a second insulating layer covering the first memory cell array, a second bonding pad below the second insulating layer, a first conductive via on the first conductive plate, a third bonding pad connected to the first conductive via, and a first contact structure passing through the second insulating layer to connect the second bonding pad to the third bonding pad, and a second cell array structure including a second conductive plate, a second memory cell array below the second conductive plate, a third insulating layer covering the second memory cell array, a fourth bonding pad below the third insulating layer, a second conductive via on the second conductive plate, a first wiring line connected to the second conductive via, and a second contact structure passing through the third insulating layer to connect the fourth bonding pad to the first wiring line, wherein the first bonding pad is in contact with the second bonding pad, and the third bonding pad is in contact with the fourth bonding pad.

According to yet another aspect of one or more embodiments, there is provided an integrated circuit (IC) including a peripheral circuit structure including a circuit substrate, a peripheral circuit on the circuit substrate, a first insulating layer covering the peripheral circuit, and a first bonding pad disposed on the first insulating layer, a first cell array structure including a first conductive plate, a first memory cell array below the first conductive plate, a second insulating layer covering the first memory cell array, a second bonding pad below the second insulating layer, a first conductive via on the first conductive plate, a third bonding pad connected to the first conductive via, and a first contact structure passing through the second insulating layer to connect the second bonding pad to the first conductive plate, a second cell array structure including a second conductive plate, a second memory cell array below the second conductive plate, a third insulating layer covering the second memory cell array, a fourth bonding pad below the third insulating layer, and a second contact structure passing through the third insulating layer to connect the fourth bonding pad to the second conductive plate, wherein the first bonding pad is in contact with the second bonding pad, and the third bonding pad is in contact with the fourth bonding pad.

### BRIEF DESCRIPTION OF THE DRAWINGS

Various embodiments will be more clearly understood from the following detailed description taken in conjunction with the accompanying drawings, in which:

FIG. 1 is a block diagram illustrating an integrated circuit (IC) device according to some embodiments;

FIG. 2 is a perspective view schematically illustrating an IC device according to some embodiments;

FIG. 3 is an equivalent circuit diagram illustrating a memory cell array of an IC device according to some embodiments;

FIG. 4 is a partially enlarged plan view illustrating components of an IC device according to some embodiments, FIG. 5 is a cross-sectional view taken along line X-X′ of FIG. 4, FIG. 6 is an enlarged view of a portion AA in FIG. 5, FIG. 7 is an enlarged view of a portion BB in FIG. 5, and FIG. 8 is an enlarged view of a portion CC in FIG. 5;

FIGS. 9A to 9E are plan views illustrating various modifications of a region of the partially enlarged view of FIG. 4, according to some embodiments;

FIGS. 10 and 11 are cross-sectional views illustrating IC devices according to some embodiments;

FIGS. 12A to 12E are cross-sectional views illustrating a sequential process of a method of manufacturing an IC device according to some embodiments;

FIG. 13 is a diagram illustrating an electronic system including an IC device according to some embodiments;

FIG. 14 is a perspective view illustrating an electronic system including an IC device according to some embodiments; and

FIG. 15 is a cross-sectional view illustrating a semiconductor package including an IC device according to some embodiments.

### DETAILED DESCRIPTION

Hereinafter, various embodiments are described in detail with reference to the accompanying drawings.

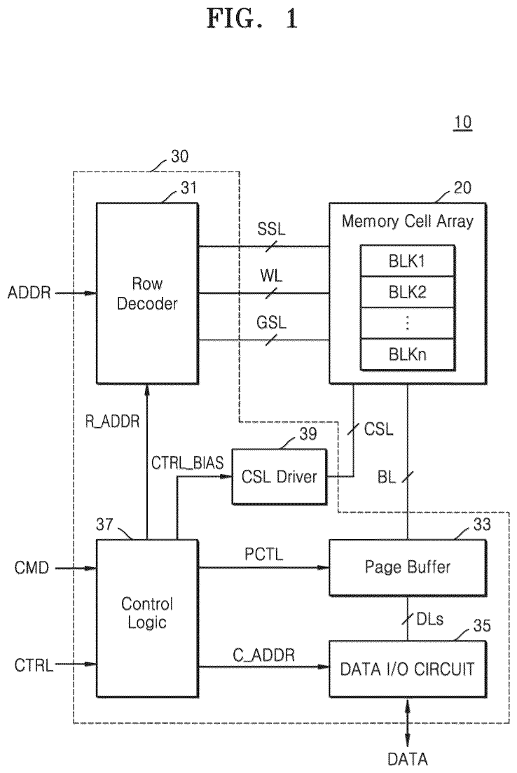

FIG. 1 is a block diagram illustrating an integrated circuit (IC) device 10 according to some embodiments.

Referring to FIG. 1, the IC device 10 may include a memory cell array 20 and a peripheral circuit 30.

The memory cell array 20 includes a plurality of memory cell blocks BLK1, BLK2, . . . , BLKn. Each of the memory cell blocks BLK1, BLK2, . . . , BLKn may include a plurality of memory cells. The memory cell blocks BLK1, BLK2, . . . , BLKn may be connected to the peripheral circuit 30 through a bit line BL, a word line WL, a string select line SSL, and a ground select line GSL.

The memory cell array 20 may be connected to a page buffer 33 through the bit line BL, and may be connected to a row decoder 31 through the word line WL, the string select line SSL, and the ground select line GSL. In the memory cell array 20, each of the memory cells included in the memory cell blocks BLK1, BLK2, . . . , BLKn may be a flash memory cell. The memory cell array 20 may include a 3D memory cell array. The 3D memory cell array may include a plurality of NAND strings, and each of the NAND strings may include a plurality of memory cells connected to a plurality of vertically stacked word lines WL.

The peripheral circuit 30 may include the row decoder 31, the page buffer 33, a data input/output (I/O) circuit 35, a control logic 37, and a common source line (CSL) driver 39. Although not shown, the peripheral circuit 30 may include various additional circuits, such as a voltage generating circuit generating various voltages for the operation of the IC device 10, an error correction circuit correcting errors in data read from the memory cell array 20, an I/O interface, etc.

The peripheral circuit 30 may receive an address ADDR, a command CMD, and a control signal CTRL from the outside of the IC device 10, and may transmit and receive data DATA to and from a device outside the IC device 10.

A detailed configuration of the peripheral circuit 30 is as follows.

In response to the address ADDR from the outside, the row decoder 31 may select at least one of the memory cell blocks BLK1, BLK2, . . . , BLKn and may select a word line WL, a string select line SSL, and a ground select line GSL of the selected memory cell block. The row decoder 31 may transmit a voltage for performing a memory operation to the word line WL of the selected memory cell block.

The page buffer 33 may be connected to the memory cell array 20 through a bit line BL. During a program operation, the page buffer 33 may operate as a write driver to apply a voltage according to the data DATA to be stored in the memory cell array 20 to the bit line BL, and during a read operation, the page buffer 33 may operate as a sense amplifier to sense the data DATA stored in the memory cell array 20. The page buffer 33 may operate according to a control signal PCTL provided from the control logic 37.

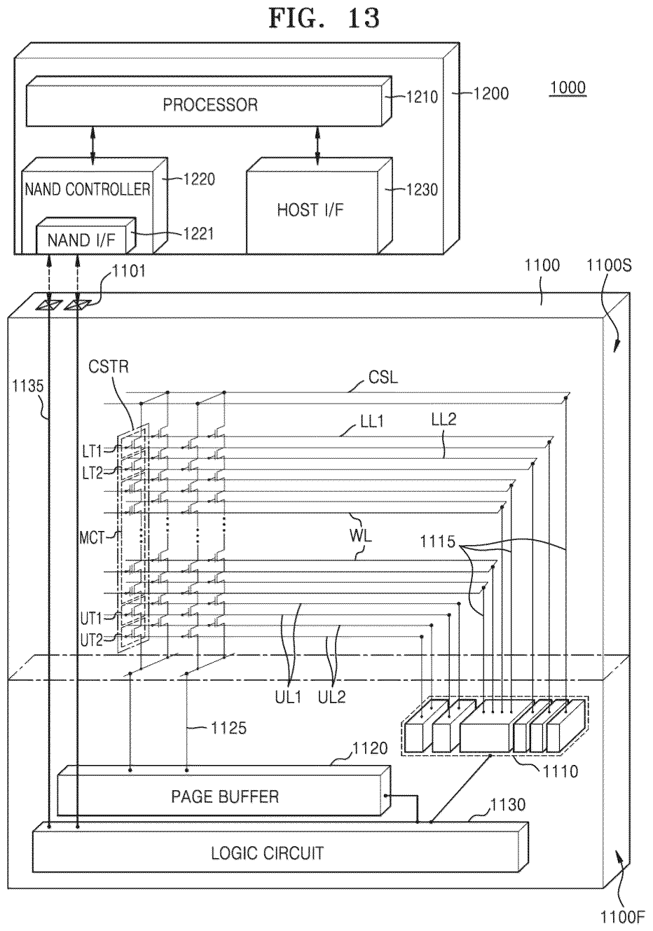

The data I/O circuit 35 may be connected to the page buffer 33 through data lines DLs. During a program operation, the data I/O circuit 35 may receive the data DATA from a controller 1200 (refer to FIG. 13) and provide program data DATA to the page buffer 33 based on the column address C_ADDR provided from the control logic 37. During a read operation, the data I/O circuit 35 transfers the read data DATA stored in the page buffer 33 to the controller 1200 (refer to FIG. 13) based on the column address C_ADDR provided from the control logic 37. The data I/O circuit 35 may transfer an input address or command to the control logic 37 or row decoder 31.

The control logic 37 may receive the command CMD and the control signal CTRL from the controller 1200 (refer to FIG. 13). The control logic 37 may provide the row address R_ADDR to the row decoder 31 and the column address C_ADDR to the data I/O circuit 35. The control logic 37 may generate various internal control signals used in the IC device 10 in response to the control signal CTRL. For example, the control logic 37 may adjust a voltage level provided to the word line WL and the bit line BL when a memory operation, such as a program operation or an erase operation, is performed.

The CSL driver 39 may be connected to the memory cell array 20 through a common source line CSL. In some embodiments, the common source line (CSL) may include a plurality of common source lines (CSL). The CSL driver 39 may apply a common source voltage (e.g., a power supply voltage) or a ground voltage to the common source line CSL based on control by the control logic 37.

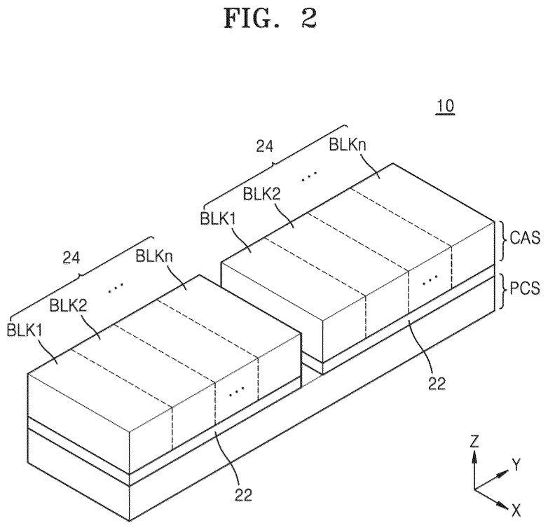

FIG. 2 is a perspective view schematically illustrating the IC device 10 according to some embodiments.

Referring to FIG. 2, the IC device 10 includes a peripheral circuit structure PCS and a cell array structure (CAS) overlapping each other in a vertical direction (a Z direction).

The cell array structure CAS may include the memory cell array 20 (refer to FIG. 1), and the peripheral circuit structure PCS may include the peripheral circuit 30 (refer to FIG. 1).

A connection structure 22 may be located between the cell array structure CAS and the peripheral circuit structure PCS. The cell array structure CAS and the peripheral circuit structure PCS may be stacked in the vertical direction (the Z direction) through the connection structure 22. The connection structure 22 may provide physical and electrical connection between the cell array structure CAS and the peripheral circuit structure PCS. Electrical connection and data transmission between the cell array structure CAS and the peripheral circuit structure PCS may be performed through the connection structure 22.

The connection structure 22 may include a plurality of connection portions for electrically connecting the cell array structure CAS and the peripheral circuit structure PCS. The connection portions may include a metal-metal bonding structure, a through-silicon via (TSV), a back via stack (BVS), a eutectic bonding structure, a ball grid array (BGA) bonding structure, a plurality of wiring lines, a plurality of contact plugs, or combinations thereof. For example, the metal-metal bonding structure may include copper (Cu), aluminum (Al), tungsten (W), or combinations thereof.

The cell array structure CAS may include a plurality of tiles 24. Each of the tiles 24 may include the memory cell blocks BLK1, BLK2, . . . , BLKn. Each of the memory cell blocks BLK1, BLK2, . . . , BLKn may include three-dimensionally arranged memory cells.

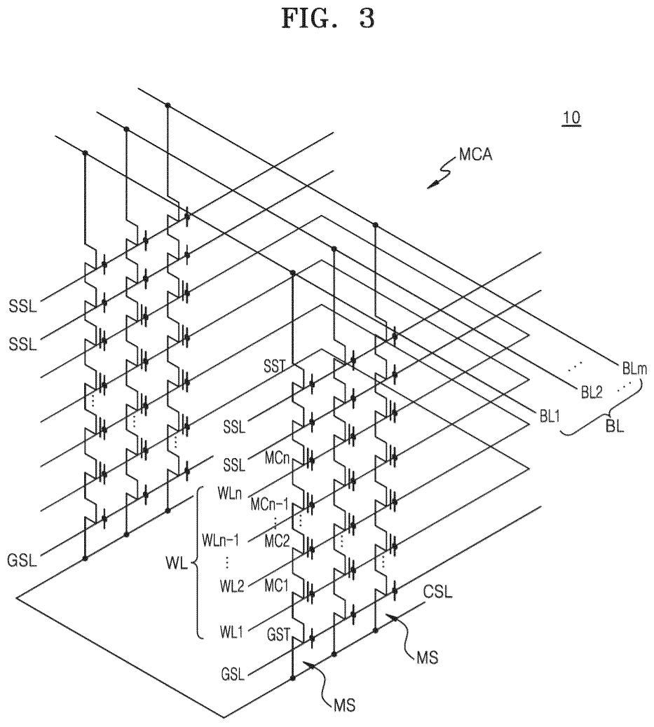

FIG. 3 is an equivalent circuit diagram illustrating a memory cell array MCA of the IC device 10 according to some embodiments.

Referring to FIG. 3, an equivalent circuit diagram of a vertical NAND flash memory device having a vertical channel structure is illustrated.

In the IC device 10, the memory cell array MCA may include a plurality of memory cell strings MS. The memory cell array MCA may include a plurality of bit lines BL, a plurality of word lines WL, at least one string select line SSL, at least one ground select line GSL, and a common source line CSL.

A plurality of memory cell strings MS may be formed between the bit lines BL and the common source line CSL. In FIG. 3, a case in which each of the memory cell strings MS includes two string select lines SSL is illustrated, but embodiments are not limited thereto. For example, each of the memory cell strings MS may include one string select line SSL.

Each of the memory cell strings MS may include a string select transistor SST, a ground select transistor GST, and a plurality of memory cell transistors MC1, MC2, . . . , MCn−1, MCn. A drain region of the string select transistor SST may be connected to the bit line BL, and a source region of the ground select transistor GST may be connected to the common source line CSL. The common source line CSL may be a region to which source regions of the ground select transistors GST are connected in common.

The string select transistor SST may be connected to the string select line SSL, and the ground select transistor GST may be connected to the ground select line GSL. The memory cell transistors MC1, MC2, . . . , MCn−1, and MCn may be connected to the corresponding word lines WL1, WL2, . . . , WLn−1, and WLn, respectively.

Each of the memory cell blocks BLK1, BLK2, . . . , BLKn described above with reference to FIGS. 1 and 2 may include the memory cell array MCA having the circuit configuration described above with reference to FIG. 3.

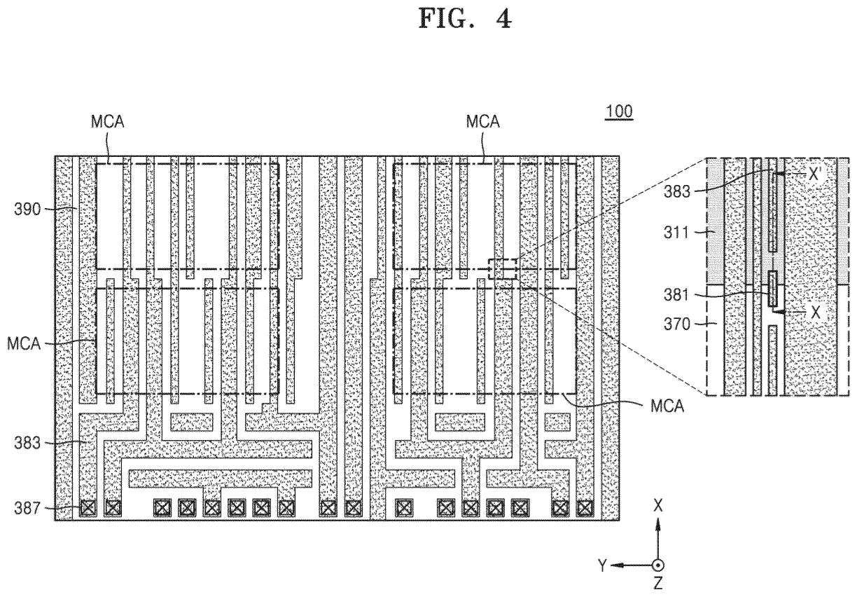

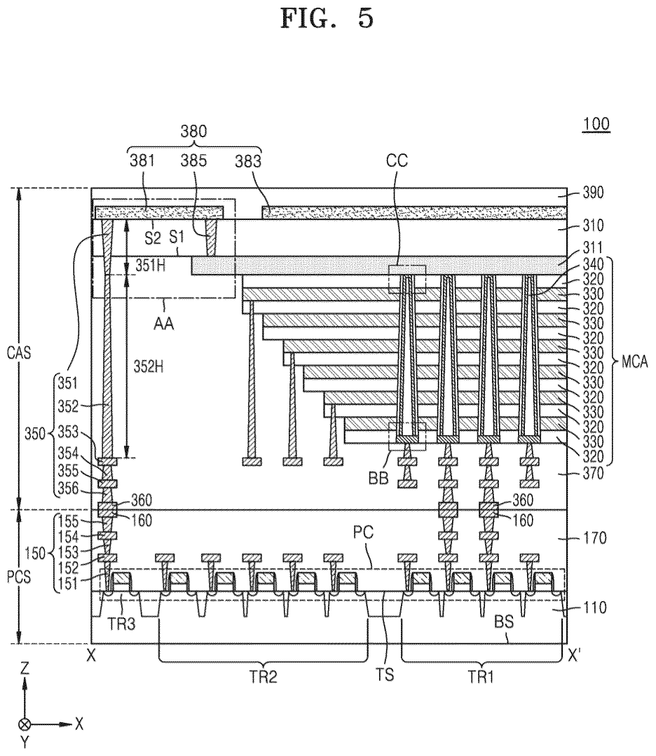

FIG. 4 is a plan view and partially enlarged view illustrating components of an IC device 100 according to some embodiments, FIG. 5 is a cross-sectional view taken along line X-X′ of FIG. 4, FIG. 6 is an enlarged view of a portion AA in FIG. 5, FIG. 7 is an enlarged view of a portion BB in FIG. 5, and FIG. 8 is an enlarged view of a portion CC in FIG. 5.

Referring to FIGS. 4 to 8 together, the IC device 100 may include a peripheral circuit structure PCS and a cell array structure CAS on the peripheral circuit structure PCS.

The peripheral circuit structure PCS may be coupled to the cell array structure CAS. For example, a first bonding pad 160 of the peripheral circuit structure PCS may be coupled to a second bonding pad 360 of the cell array structure CAS. In addition, a first insulating layer 170 of the peripheral circuit structure PCS may be coupled to a second insulating layer 370 of the cell array structure CAS.

In some embodiments, the peripheral circuit structure PCS may further include at least one first dummy bonding pad (not shown) in the first insulating layer 170. In some embodiments, the cell array structure CAS may further include at least one second dummy bonding pad (not shown) in the second insulating layer 370. The first dummy bonding pad may contact the second dummy bonding pad. The first dummy bonding pad and the second dummy bonding pad may contribute to physical coupling between the peripheral circuit structure PCS and the cell array structure CAS, but may not contribute to electrical connection therebetween.

The peripheral circuit structure PCS may include a circuit substrate 110, a peripheral circuit PC on a top surface TS of the circuit substrate 110, the first insulating layer 170 covering the circuit substrate 110 and the peripheral circuit PC, and the first bonding pad 160 disposed on the first insulating layer 170. In some embodiments, the peripheral circuit structure PCS may include a first wiring structure 150.

The cell array structure CAS may include an insulating structure 310, a conductive plate 311 on a first surface S1 of the insulating structure 310, a memory cell array MCA on the conductive plate 311, the second insulating layer 370 covering the insulating structure 310 and the MCA, and the second bonding pad 360 disposed on the second insulating layer 370. In some embodiments, the cell array structure CAS may include a second wiring structure 350 and a third wiring structure 380, and may include a third insulating layer 390 insulating the third wiring structure on a second surface S2 of the insulating structure 310.

First, a detailed configuration of the peripheral circuit structure PCS is described.

The circuit substrate 110 may have the top surface TS and a bottom surface BS opposing each other. The circuit substrate 110 may be a bulk wafer or a wafer including epitaxial growth. The circuit substrate 110 may include a group IV semiconductor material, a group III-V semiconductor material, or a group II-VI semiconductor material. The group IV semiconductor material may include, for example, silicon (Si), germanium (Ge), or silicon germanium (SiGe). The group III-V semiconductor material may include, for example, gallium arsenide (GaAs), indium phosphide (InP), gallium phosphide (GaP), indium arsenide (InAs), indium antimony (InSb), or indium gallium arsenide (InGaAs). The group II-VI semiconductor material may include, for example, zinc telluride (ZnTe) or cadmium sulfide (CdS).

The peripheral circuit PC may include a plurality of transistors on the circuit substrate 110. The plurality of transistors may include a first transistor TR1, a second transistor TR2, and a third transistor TR3. A shallow trench isolation layer may be disposed between each of the transistors TR1, TR2, and TR3.

The first transistor TR1 may be a component of the data I/O circuit 35 (refer to FIG. 1).

The second transistor TR2 may be a component of the row decoder 31 (refer to FIG. 1), the page buffer 33 (refer to FIG. 1), or the control logic 37 (refer to FIG. 1).

The third transistor TR3 may be a component of the CSL driver 39 (refer to FIG. 1). As is described in detail below, the third transistor TR3 may be electrically connected to the conductive plate 311 through the first wiring structure 150, the first bonding pad 160, the second bonding pad 360, the second wiring structure 350, and the third wiring structure 380.

The first wiring structure 150 may connect the peripheral circuit PC to the first bonding pad 160. The first wiring structure 150 may include a first via 151, a first conductive line 152, a second via 153, a second conductive line 154, and a third via 155. In FIG. 5, the first wiring structure 150 is illustrated as including three layers of vias 151, 153, and 155 and two layers of conductive lines 152 and 154, but embodiments are not limited thereto.

The first wiring structure 150 may include a metal material, such as copper (Cu), aluminum (Al), tungsten (W), silver (Ag), or gold (Au). In some embodiments, the first wiring structure 150 may further include a barrier material, such as titanium (Ti), tantalum (Ta), titanium nitride (TiN), or tantalum nitride (TaN) to prevent diffusion of the metal material into the first insulating layer 170.

The first insulating layer 170 may be disposed to cover the circuit substrate 110 and the peripheral circuit PC. The first insulating layer 170 may include, for example, silicon oxide, silicon nitride, a low-k material, or combinations thereof. The low-k material may be a material having a dielectric constant lower than that of silicon oxide, for example, phosphosilicate glass (PSG), borophosphosilicate glass (BPSG), fluorosilicate glass (FSG), organosilicate glass (OSG), spin-on-glass (SOG), or combinations thereof.

Next, a configuration of the cell array structure (CAS) is described in detail as follows.

The insulating structure 310 may have the first surface S1 and the second surface S2 opposing each other. The insulating structure 310 may include silicon oxide, silicon nitride, silicon oxynitride, or combinations thereof.

The conductive plate 311 may be disposed on the first surface S1 of the insulating structure 310. The conductive plate 311 may include a metal material, a semiconductor material, or combinations thereof. In some embodiments, the conductive plate 311 may have a structure in which a polysilicon layer 311a, a barrier metal layer 311b, and a metal layer 311c are sequentially stacked. In some embodiments, the conductive plate 311 may have a structure in which the polysilicon layer 311a and the metal layer 311c are stacked; in other words, the barrier metal layer 311b may be omitted. The conductive plate 311 may function as a common source line (CSL, refer to FIG. 3).

The memory cell array MCA may include a plurality of interlayer insulating layers 320 and a plurality of gate layers 330 alternately stacked on the conductive plate 311 and a plurality of channel structures 340 passing through the interlayer insulating layers 320 and the gate layers 320. The gate layers 330 may be formed in a step structure in which a planar area gradually decreases away from the conductive plate 311.

The interlayer insulating layers 320 may include silicon oxide, silicon nitride, a low-k material, or combinations thereof. The interlayer insulating layers 320 may include a material different from a material constituting the second insulating layer 370.

The gate layers 330 may include a metal material, such as copper (Cu), aluminum (Al), tungsten (W), silver (Ag), or gold (Au). In some embodiments, each gate layer 330 may further include titanium (Ti), tantalum (Ta), titanium nitride (TiN), or tantalum nitride (TaN) to prevent the metal material from diffusing into the interlayer insulating layers 320.

The channel structure 340 may be located in a channel hole CH passing through the interlayer insulating layers 320 and the gate layers 330 in a vertical direction (a Z direction). Each channel structure 340 may include a gate insulating layer 341 on a side surface of the channel hole CH, a channel layer 342 on the gate insulating layer 341, a filling insulating layer 343 on the channel layer 342, and a channel pad 344 filling one end of the channel hole CH.

The gate insulating layer 341 may include a blocking insulating layer 341a, a charge storage layer 341b, and a tunneling insulating layer 341c sequentially stacked on the channel hole CH. The blocking insulating layer 341a may include, for example, silicon oxide, silicon nitride, metal oxide having permittivity higher than that of silicon oxide, or combinations thereof. The charge storage layer 341b may include, for example, silicon nitride, boron nitride, polysilicon, or combinations thereof. The tunneling insulating layer 341c may include, for example, metal oxide or silicon oxide.

The channel layer 342 may surround a side surface and one end of the filling insulating layer 343. The channel layer 342 may include a group IV semiconductor material, a group III-V semiconductor material, or a group II-VI semiconductor material. In some embodiments, the channel layer 342 may include polysilicon.

The filling insulating layer 343 may fill a space surrounded by the channel layer 342 and the channel pad 344. The filling insulating layer 343 may include, for example, silicon nitride, silicon oxide, a low-k material, or combinations thereof. In some embodiments, the filling insulating layer 343 may include silicon oxide.

The channel pad 344 may contact the channel layer 342 and the filling insulating layer 343. The channel pad 344 may include a semiconductor material, such as silicon (Si), germanium (Ge), or silicon germanium (SiGe), a metal material, such as tungsten (W), titanium (Ti), aluminum (Al), copper (Cu), gold (Au), or silver (Ag), a metal nitride, such as titanium nitride (TiN) or tantalum nitride (TaN), or combinations thereof.

The second wiring structure 350 may include a contact structure for connecting the third wiring structure 380 to the second bonding pad 360. The second wiring structure 350 may include a first contact plug 351, a second contact plug 352, a third conductive line 353, a fourth via 354, a fourth conductive line 355, and a fifth via 356 In FIG. 5, the second wiring structure 350 is illustrated as including two layers of contact plugs 351 and 352, two layers of conductive lines 353 and 355, and two layers of vias 354 and 356, but embodiments are not limited thereto.

In the IC device 100, the contact structure may include a first contact plug 351 passing through the insulating structure 310 and a second contact plug 352 passing through the second insulating layer 370. The first contact plug 351 and the second contact plug 352 may have different shapes. In some embodiments, the first contact plug 351 may be tapered to narrow toward the circuit substrate 110 in the vertical direction (the Z direction). That is, a width of the first contact plug 351 may decrease as a distance from the circuit substrate 110 decreases. In some embodiments, the second contact plug 352 may be tapered to widen toward the circuit substrate 110 in the vertical direction (the Z direction). In other words, a width of the second contact plug 352 may increase as a distance from the circuit substrate 110 decreases. In some embodiments, a first height 351H of the first contact plug 351 in the vertical direction (the Z direction) may be less than a second height 352H in the vertical direction (the Z direction) of the second contact plug 352.

The second wiring structure 350 may include a metal material, such as copper (Cu), aluminum (Al), tungsten (W), silver (Ag), or gold (Au). In some embodiments, the second wiring structure 350 may include a barrier material, such as titanium (Ti), tantalum (Ta), titanium nitride (TiN), or tantalum nitride (TaN) to prevent diffusion of the metal material into the second insulating layer 370.

The second insulating layer 370 may include, for example, silicon oxide, silicon nitride, a low-k material, or combinations thereof. The low-k material is a material having a dielectric constant lower than that of silicon oxide, and may include, for example, PSG, BPSG, FSG, OSG, SOG, or combinations thereof.

A third wiring structure 380 may be formed inside the insulating structure 310 and on the second surface S2 of the insulating structure 310. The third wiring structure 380 may include a first wiring line 381, a second wiring line 383, a conductive via 385, and an I/O pad 387.

The first wiring line 381 may be disposed on the second surface S2 of the insulating structure 310. The first wiring line 381 may be electrically connected to the conductive plate 311 through the conductive via 385 and may be electrically connected to the second bonding pad 360 through the second wiring structure 350.

The first wiring line 381 and the second wiring line 383 may be spaced apart from each other at the same vertical level on the second surface S2 of the insulating structure 310. In some embodiments, each of the first wiring line 381 and the second wiring line 383 may include copper (Cu), aluminum (Al), tungsten (W), silver (Ag), or gold (Au).

In a plan view, the first wiring line 381 may have a first length in a first horizontal direction (an X direction) so that a portion of the first wiring line 381 overlaps an edge of the conductive plate 311, and the second wiring line 383 may have a second length in the first horizontal direction (the X direction) so that the second wiring line 383 overlaps across the conductive plate 311. In other words, in some embodiments, the entire second length of the second wiring line 383 may overlap the conductive plate 311, as illustrated in FIG. 5. In some embodiments, the second length of the second wiring line 383 may be longer than the first length of the first wiring line 381.

In some embodiments, a length of an overlap region OL in which the first wiring line 381 overlaps the conductive plate 311 in the first horizontal direction (the X direction) may be about 5 μm or less. That is, the first wiring line 381 may be located across the edge of the conductive plate 311. The second wiring line 383 may be provided in plural and the second wiring lines 383 may be respectively located on sides of the first wiring line 381 in a second horizontal direction (a Y direction) perpendicular to the first horizontal direction (the X direction). The arrangement relationship between the first wiring line 381 and the second wiring line 383 may vary, which will be described in detail below.

The conductive via 385 may be formed to pass through the insulating structure 310. The conductive via 385 may directly contact the conductive plate 311 and the first wiring line 381 to provide electrical connection therebetween. The conductive via 385 may be tapered to widen away from the conductive plate 311. In other words, a width of the conductive via 385 may increase as a distance from the conductive plate 311 increases. In some embodiments, the conductive via 385 may be located only in the overlap region OL.

The conductive via 385 may include a metal material, such as copper (Cu), aluminum (Al), tungsten (W), silver (Ag), or gold (Au). In some embodiments, the conductive via 385 may include a barrier material, such as tantalum (Ta), titanium (Ti), tantalum nitride (TaN), or titanium nitride (TiN) to prevent the metal material from diffusing into the insulating structure 310.

The I/O pad 387 may be disposed on the second surface S2 of the insulating structure 310 (see FIG. 4). The I/O pad 387 may connect the peripheral circuit PC to the controller 1200 (refer to FIG. 13). A portion of an upper surface of the I/O pad 387 may be exposed from the third insulating layer 390. A connection structure, such as a bonding wire, may be bonded to the exposed upper surface of the I/O pad 387 to be connected to the outside of the IC device 100. In some embodiments, the I/O pad 387 may perform a power connection function and/or a ground connection function. The I/O pad 387 may include, for example, a metal material, such as copper (Cu), aluminum (Al), tungsten (W), silver (Ag), or gold (Au).

The I/O pad 387 may be located at substantially the same level as levels of the first and second wiring lines 381 and 383. However, embodiments are not limited thereto and the I/O pad 387 may be located at a level higher than a level of each of the first and second wiring lines 381 and 383.

The third insulating layer 390 may be located to surround the first wiring line 381, the second wiring line 383, and the I/O pad 387 on the second surface S2 of the insulating structure 310. An open hole (not shown) may be located in the third insulating layer 390 to expose a portion of the upper surface of the I/O pad 387. The third insulating layer 390 may include, for example, silicon nitride, silicon oxide, a low-k material, or combinations thereof.

In order to meet excellent performance and economic feasibility, it is required to increase the degree of integration of the IC device 100. In particular, the degree of integration of memory devices is an important factor in determining the economic feasibility of products. Accordingly, a vertical memory device having a three-dimensional (3D) structure is required. In general, in a related art device, a through-electrode is formed in a partial region of the memory cell array MCA to electrically connect the memory cell array MCA to a CSL driver (refer to FIG. 1). Accordingly, a memory cell cannot be located in the partial region (referred to as a through-electrode region) of the memory cell array MCA in which the through-electrode is located.

According to the IC device 100 of some embodiments, in the vertical memory device, a bypass wiring BP (see FIG. 6) connecting the conductive plate 311 to the CSL driver 39 (refer to FIG. 1) is located outside the memory cell array MCA. Accordingly, the conductive plate 311 may be electrically connected to the CSL driver 39 (refer to FIG. 1) through the bypass wiring BP including the second wiring structure 350 and the third wiring structure 380.

Ultimately, because there is no need to separately form a through-electrode region in the memory cell array MCA of the IC device 100 according to various embodiments, the degree of integration may increase by further securing a through wiring line arrangement region in the memory cell.

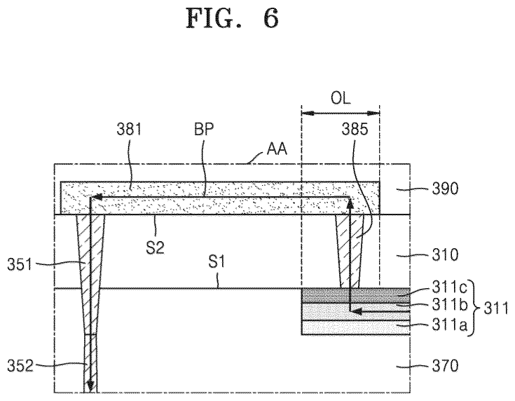

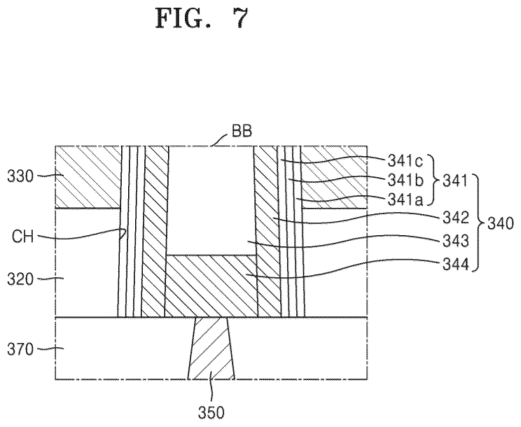

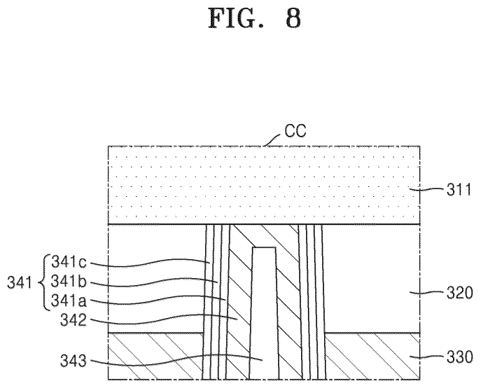

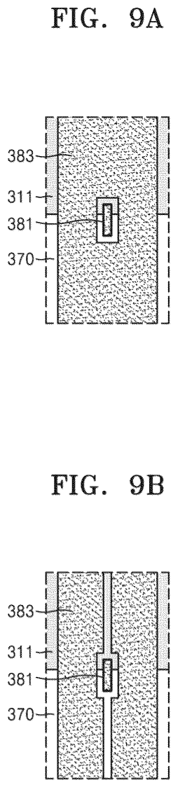

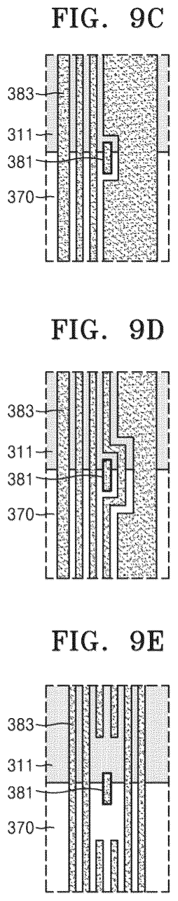

FIGS. 9A to 9E are plan views illustrating various modifications of a region of the partially enlarged view of FIG. 4, according to some embodiments.

Referring to FIGS. 9A to 9E, the first wiring line 381 may be disposed across the edge of the conductive plate 311, and the second wiring line 383 (see, e.g., FIG. 9A) or the second wiring lines 383 (see, e.g., FIGS. 9B-9E) may be formed on sides of the first wiring line 381 in various forms.

Arrangement forms of the first and second wiring lines 381 and 383 are not limited to those illustrated in FIGS. 9A to 9E, and, in some embodiments, a position, arrangement, shape, direction, number, and positional relationship of the first and second wiring lines 381 and 383 may vary depending on a circuit configuration of the IC device 100.

In some embodiments, as shown in FIGS. 9A and 9B, the upper region of the conductive plate 311 and the second insulating layer 370 may include a relatively smaller number of second wiring lines 383 having a relatively wide width in the second horizontal direction (Y direction) to reduce resistance and ensure a smooth current flow.

In some embodiments, as shown in FIGS. 9C to 9E, the upper region of the conductive plate 311 and the second insulating layer 370 may include a relatively greater number of second wiring lines 383 to transmit various signals. Depending on the design of the second wiring line 383, a greater number of second wiring lines 383 may be arranged in the same area. In some embodiments, the second wiring line 383 may include a bent portion or an end portion to compensate for an increase in area due to the second wiring line 383 in the form of the bent portion or end portion, and thus a greater number of second wiring lines 383 may be located in the same area.

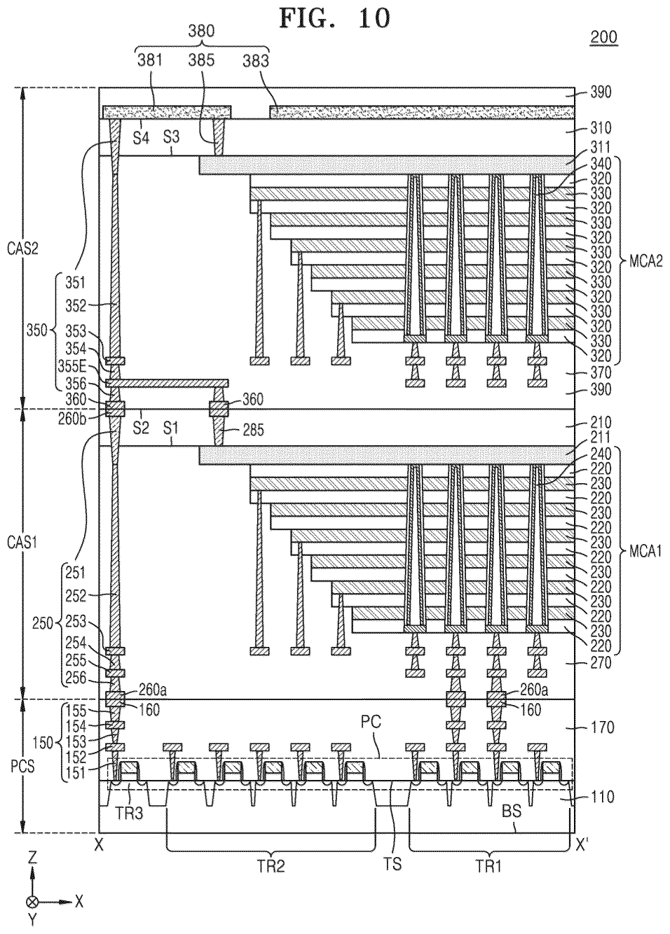

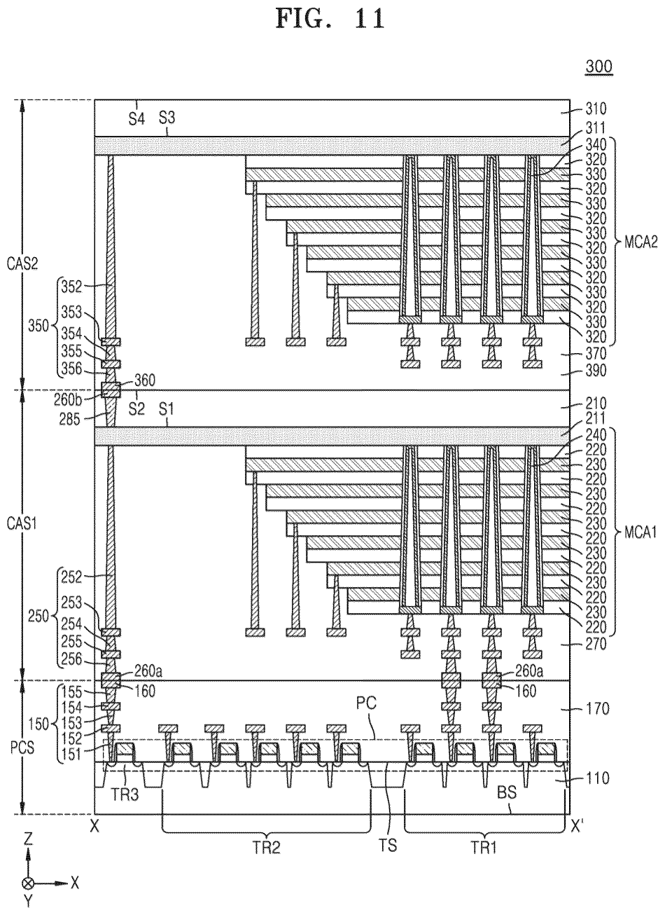

FIGS. 10 and 11 are cross-sectional views illustrating IC devices 200 and 300, respectively, according to some embodiments.

Most of the components constituting the IC devices 200 and 300 and materials constituting the components to be described below are substantially the same as or similar to those described above with reference to FIGS. 4 to 8. Therefore, for convenience of description, repeated description thereof is omitted for conciseness and the description will focus on differences from the IC device 100 described above.

In addition, those skilled in the art may understand that the expression representing first to fifth may be different than for the same components described above for convenience of description but do not indicate different components or functions of those components from description from that of the IC device 100 described above.

Referring to FIG. 10, the IC device 200 may include the peripheral circuit structure PCS and first and second cell array structures CAS1 and CAS2 on the peripheral circuit structure PCS.

The peripheral circuit structure PCS may be coupled to the first cell array structure CAS1. For example, a first bonding pad 160 of the peripheral circuit structure PCS may be coupled to a second bonding pad 260a of the first cell array structure CAS1. The first cell array structure CAS1 may be coupled to the second cell array structure CAS2. For example, a third bonding pad 260b of the first cell array structure CAS1 may be coupled to a fourth bonding pad 360 of the second cell array structure CAS2.

The peripheral circuit structure PCS may include the circuit substrate 110, the peripheral circuit PC on a top surface TS of the circuit substrate 110, the first insulating layer 170 covering the circuit substrate 110 and the peripheral circuit PC, and the first bonding pad 160 disposed on the first insulating layer 170. The peripheral circuit structure PCS may include the first wiring structure 150.

The first cell array structure CAS1 may include a first insulating structure 210, a first conductive plate 211 on the first surface S1 of the first insulating structure 210, a first memory cell array MCA1 on the first conductive plate 211, a second insulating layer 270 covering the first insulating structure 210 and the first memory cell array MCA1, a second bonding pad 260a disposed on the second insulating layer 270, and a third bonding pads 260b disposed on the first insulating structure 210. The first cell array structure CAS1 may include a first conductive via 285 and a second wiring structure 250.

The second cell array structure CAS2 may include a second insulating structure 310, a second conductive plate 311 on a third surface S3 of the second insulating structure 310, a second memory cell array MCA2 on the second conductive plate 311, a third insulating layer 370 covering the second insulating structure 310 and the second memory cell array MCA2, and fourth bonding pads 360 disposed on the third insulating layer 370. The second cell array structure CAS2 may include a third wiring structure 350 and a fourth wiring structure 380, and may include a fourth insulating layer 390 insulating the fourth wiring structure 380 on a fourth surface S4 of the second insulating structure 310.

In the IC device 200, an extended wiring line 355E may be disposed in the third insulating layer 370 of the second cell array structure CAS2 and may electrically connect the fourth bonding pads 360 to each other. The first conductive plate 211 of the first cell array structure CAS1 may be electrically connected to the second wiring structure 250 through the extended wiring line 355E.

In the IC device 200, the first conductive plate 211 and the second conductive plate 311 may correspond to the common source line CSL (refer to FIG. 3), and the peripheral circuit PC may include a third transistor TR3 corresponding to the CSL driver 39 (refer to FIG. 1).

In the IC device 200, the first conductive plate 211 may form a first bypass wiring with the extended wiring line 355E and the second wiring structure 250 to be electrically connected to the third transistor TR3, and the second conductive plate 311 may form a bypass wiring with the first wiring line 381 and the third wiring structure 350 to be electrically connected to the third transistor TR3. Thus, the first bypass wiring may connect the first conductive plate 211 to the third transistor TR3 of CSL driver 39 (refer to FIG. 1) and may be located outside the first memory cell array MCA1, and the second bypass wiring may connect the second conductive plate 311 to the third transistor TR3 of CSL driver 39 and may be located outside the second memory cell array MCA2.

Referring to FIG. 11, the IC device 300 may include the peripheral circuit structure PCS and the first and second cell array structures CAS1 and CAS2 on the peripheral circuit structure PCS.

The peripheral circuit structure PCS may be coupled to the first cell array structure CAS1. For example, a first bonding pad 160 of the peripheral circuit structure PCS may be coupled to the second bonding pad 260a of the first cell array structure CAS1. The first cell array structure CAS1 may be coupled to the second cell array structure CAS2. For example, the third bonding pad 260b of the first cell array structure CAS1 may be coupled to the fourth bonding pad 360 of the second cell array structure CAS2.

The peripheral circuit structure PCS may include the circuit substrate 110, the peripheral circuit PC on a top surface TS of the circuit substrate 110, the first insulating layer 170 covering the circuit substrate 110 and the peripheral circuit PC, and the first bonding pad 160 disposed on the first insulating layer 170. The peripheral circuit structure PCS may include the first wiring structure 150.

The first cell array structure CAS1 may include the first insulating structure 210, the first conductive plate 211 on the first surface S1 of the first insulating structure 210, the first memory cell array MCA1 on the first conductive plate 211, the second insulating layer 270 covering the first insulating structure 210 and the first memory cell array MCA1, the second bonding pad 260a disposed on the second insulating layer 270, and the third bonding pads 260b disposed on the first insulating structure 210. The first cell array structure CAS1 may include the first conductive via 285 and the second wiring structure 250.

The second cell array structure CAS2 may include the second insulating structure 310, the second conductive plate 311 on the third surface S3 of the second insulating structure 310, the second memory cell array MCA2 on the second conductive plate 311, the third insulating layer 370 covering the second insulating structure 310 and the second memory cell array MCA2, and the fourth bonding pad 360 disposed on the third insulating layer 370. The second cell array structure CAS2 may include a third wiring structure 350.

In some embodiments, the first to fourth bonding pads 160, 260a, 260b, and 360 and the first to third wiring structures 150, 250, and 350 that are electrically connected to each other may be all aligned in a vertical direction.

In some embodiments, the first conductive via 285 may be tapered to narrow toward the circuit substrate 110 in the vertical direction (the Z direction), and each of the second and third wiring structures 250 and 350 may be tapered to widen toward the circuit substrate 110 in the vertical direction (the Z direction).

In the IC device 300, the first conductive plate 211 and the second conductive plate 311 correspond to the common source line CSL (refer to FIG. 3), and the peripheral circuit PC may include the third transistor TR3 corresponding to the CSL driver 39 (refer to FIG. 1).

In the IC device 300, the first conductive plate 211 may be electrically connected to the third transistor TR3 through the first and second wiring structures 150 and 250, and the second conductive plate 311 may be electrically connected to the third transistor TR3 through the first to third wiring structures 150, 250, and 350.

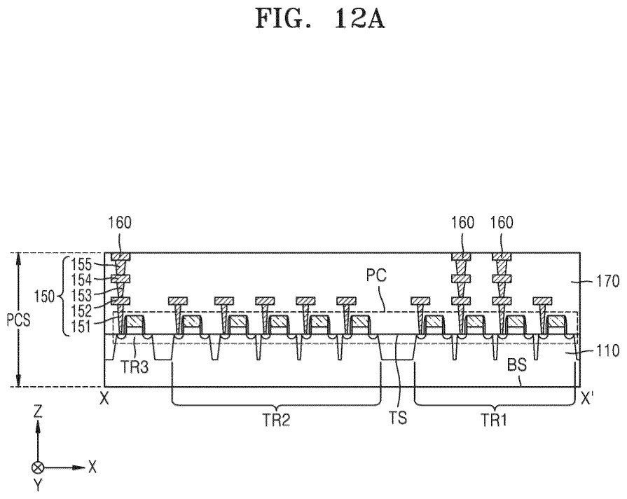

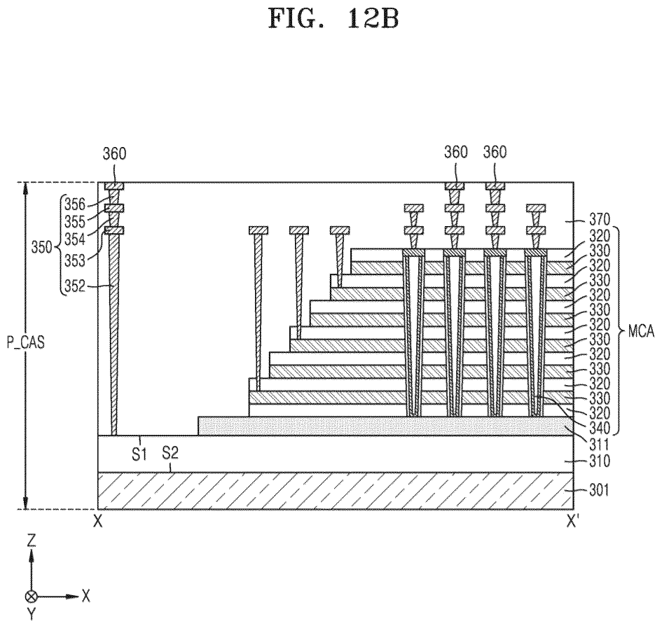

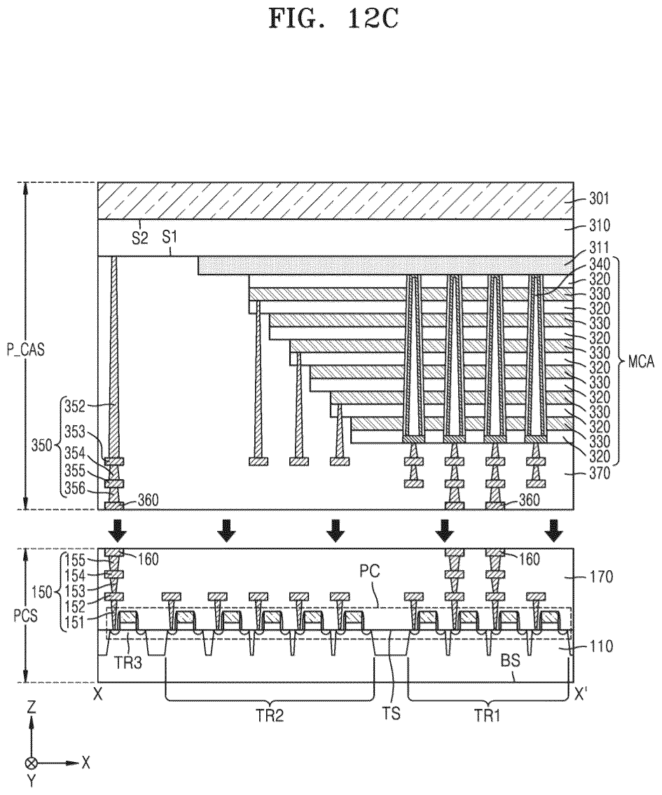

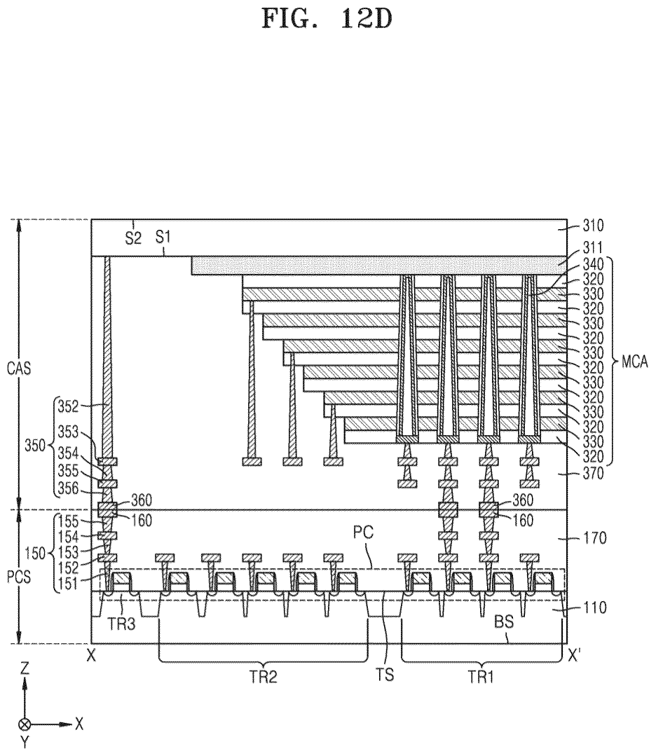

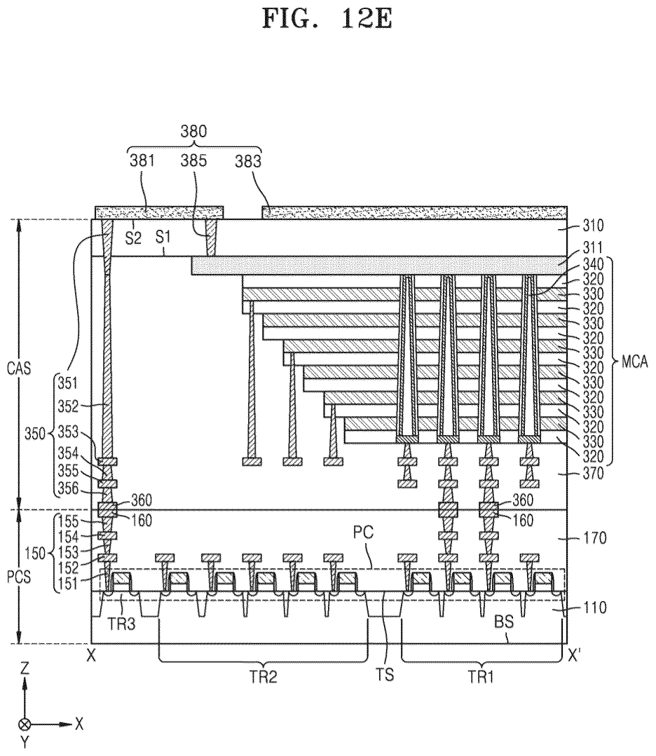

FIGS. 12A to 12E are cross-sectional views illustrating a sequential process of a method of manufacturing an IC device according to some embodiments.

Referring to FIG. 12A, the peripheral circuit structure PCS including the circuit substrate 110 having the top surface TS and the bottom surface BS may be formed.

The peripheral circuit structure PCS may include the peripheral circuit PC on the top surface TS of the circuit substrate 110, the first insulating layer 170 covering the circuit substrate 110 and the peripheral circuit PC, and the first bonding pad 160 disposed on the first insulating layer 170. The peripheral circuit structure PCS may include the first wiring structure 150.

Referring to FIG. 12B, a preliminary cell array structure P_CAS, which is a portion of the cell array structure CAS (refer to FIG. 5), may be formed.

The preliminary cell array structure P_CAS may include a base substrate 301, the insulating structure 310, the conductive plate 311 on the first surface S1 of the insulating structure 310, the second insulating layer 370 covering the insulating structure 310 and the memory cell array MCA, and the second bonding pad 360 disposed on the second insulating layer 370. In some embodiments, the preliminary cell array structure P_CAS may include the second wiring structure 350. In some embodiments, the preliminary cell array structure P_CAS may not include the third wiring structure 380 (refer to FIG. 5).

Referring to FIG. 12C, after the preliminary cell array structure P_CAS is aligned on the peripheral circuit structure PCS to overlap the peripheral circuit structure PCS in the vertical direction (the Z direction), the first bonding pad 160 included in the peripheral circuit structure PCS may be bonded to the second bonding pad 360 included in the preliminary cell array structure P_CAS.

In some embodiments, the first bonding pad 160 included in the peripheral circuit structure PCS may be directly bonded to the second bonding pad 360 included in the preliminary cell array structure P_CAS by pressing the preliminary cell array structure P_CAS in the direction of the arrows, without a separate adhesive layer. For example, in a state in which the first bonding pad 160 and the second bonding pad 360 face each other, they may be pressed in a direction toward each other such that bonds at an atomic level are formed, thereby bonding the first bonding pad 160 and the second bonding pad 360 to each other.

In some embodiments, before bonding the first bonding pad 160 to the second bonding pad 360, a surface treatment process, such as a hydrogen plasma treatment, may be further performed on a surface of the preliminary cell array structure P_CAS in which the first bonding pad 160 is exposed and a surface of the peripheral circuit structure PCS in which the second bonding pad 360 is exposed in order to reinforce the bonding strength thereof.

Referring to FIG. 12D, the second surface S2 of the insulating structure 310 may be exposed by removing the base substrate 301 (refer to FIG. 12C) from the preliminary cell array structure P_CAS.

In some embodiments, a grinding process, a wet etching process, a dry etching process, or combinations thereof may be used to remove the base substrate 301 (refer to FIG. 12C).

Referring to FIG. 12E, the first contact plug 351 and the third wiring structure 380 may be formed in the preliminary cell array structure P_CAS.

First, a portion of the insulating structure 310 may be removed to form a first via hole exposing the second contact plug 352, and the first contact plug 351 may be formed in the first via hole. At the same time, a portion of the insulating structure 310 may be removed to form a second via hole exposing the conductive plate 311 and the conductive via 385 may be formed in the second via hole.

Next, the first wiring line 381, the second wiring line 383, and the I/O pad 387 may be formed on the insulating structure 310.

Referring back to FIG. 5, the third insulating layer 390 covering the first wiring line 381, the second wiring line 383, and the I/O pad 387 may be formed, and an open hole (not shown) exposing an upper surface of the I/O pad 387 may be formed to complete the IC device 100 of the inventive concept.

The method of manufacturing the IC device 100 illustrated in FIGS. 4 to 8 has been described with reference to FIGS. 12A to 12E, but it may be apparent to those skilled in the art that the IC devices 200 and 300 illustrated in FIGS. 10 and 11 may be manufactured by modifying the above descriptions within the scope of the present disclosure.

FIG. 13 is a diagram illustrating an electronic system 1000 including an IC device 1100 according to some embodiments.

Referring to FIG. 13, the electronic system 1000 may include the IC device 1100 and a controller 1200 electrically connected to the IC device 1100.

The electronic system 1000 may be a storage device including the IC device 1100 or an electronic device including the storage device. For example, the electronic system 1000 may be a solid state drive (SSD), a universal serial bus (USB), a computing system, a medical device, or a communication device including at least one IC device 1100.

The IC device 1100 may be a non-volatile vertical memory device. For example, the IC device 1100 may be a NAND flash memory device including at least one of the IC devices 100, 200, and 300 described above with reference to FIGS. 4 to 11. The IC device 1100 may include a first structure 1100F and a second structure 1100S on the first structure 1100F. In some embodiments, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a plurality of word lines WL, first and second gate upper lines UL1 and UL2, first and second gate lower lines, and a plurality of memory cell strings CSTR between the bit line BL and the common source line CSL.

In the second structure 1100S, the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to embodiments.

In some embodiments, the upper transistors UT1 and UT2 may include a string select transistor, and the lower transistors LT1 and LT2 may include a ground select transistor. The gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2.

The common source line CSL, the gate lower lines LL1 and LL2, the word lines WL, and the gate upper lines UL1 and UL2 may be electrically connected to the decoder circuit 1110 through a plurality of first connection wirings 1115 extending from the first structure 1100F to the second structure 1100S. The bit lines BL may be electrically connected to the page buffer 1120 through a plurality of second connection wirings 1125 extending from the first structure 1100F to the second structure 1100S.

In the first structure 1100F, the decoder circuit 1110 and the page buffer 1120 may perform a control operation on at least one of the memory cell transistors MCT. The decoder circuit 1110 and the page buffer 1120 may be controlled by the logic circuit 1130.

The IC device 1100 may communicate with the controller 1200 through the I/O pad 1101 electrically connected to the logic circuit 1130. The I/O pad 1101 may be electrically connected to the logic circuit 1130 through an I/O connection wiring 1135 extending from the first structure 1100F to the second structure 1100S.

The controller 1200 may include a processor 1210, a NAND controller 1220, and a host interface 1230. In some embodiments, the electronic system 1000 may include a plurality of IC devices 1100, and in this configuration, the controller 1200 may control the semiconductor devices 1100.

The processor 1210 may control an overall operation of the electronic system 1000 including the controller 1200. The processor 1210 may operate according to a certain firmware, and may access the IC device 1100 by controlling the NAND controller 1220. The NAND controller 1220 may include a NAND interface 1221 that handles communication with the IC device 1100. Through the NAND interface 1221, a control command for controlling the IC device 1100, data to be written to the memory cell transistors MCT of the IC device 1100, and data to be read from a plurality of memory cell transistors MCT of the IC device 1100 may be transmitted. The host I/F 1230 may provide a communication function between the electronic system 1000 and an external host. When a control command is received from an external host through the host I/F 1230, the processor 1210 may control the IC device 1100 in response to the control command.

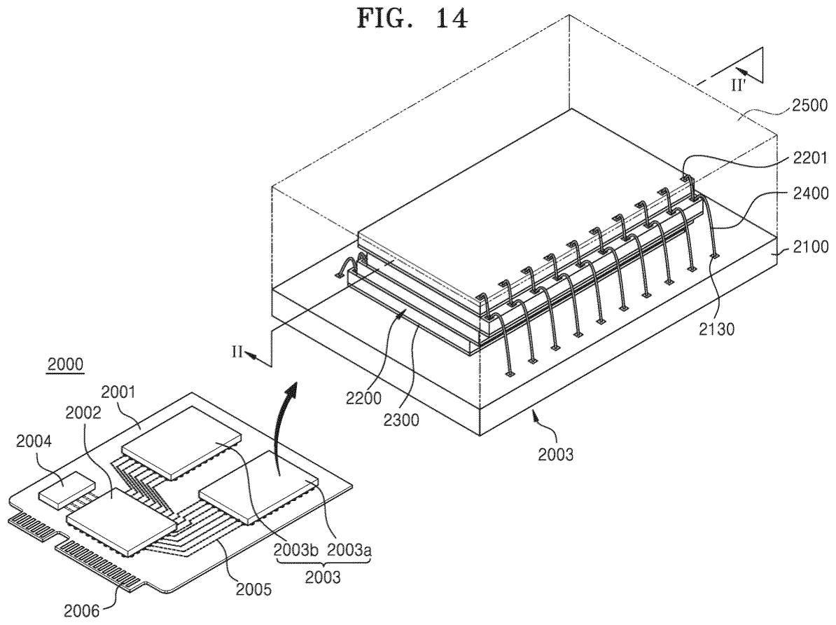

FIG. 14 is a perspective view illustrating an electronic system 2000 including an IC device according to some embodiments.

Referring to FIG. 14, the electronic system 2000 according to some embodiments may include a main board 2001, a controller 2002 mounted on the main board 2001, one or more semiconductor packages 2003, and a DRAM 2004. The semiconductor package 2003 and the DRAM 2004 may be connected to the controller 2002 by a plurality of wiring patterns 2005 formed on the main board 2001.

The main board 2001 may include a connector 2006 including a plurality of pins coupled to an external host. The number and arrangement of the pins of the connector 2006 may vary depending on a communication interface between the electronic system 2000 and the external host. In some embodiments, the electronic system 2000 may communicate with an external host according to any one of interfaces such as a universal serial bus (USB), a peripheral component interconnect express (PCI-Express), a serial advanced technology attachment (SATA), M-Phy for a universal flash storage (UFS), etc. In some embodiments, the electronic system 2000 may operate by power supplied from an external host through the connector 2006. The electronic system 2000 may further include a power management integrated circuit (PMIC) for distributing power supplied from the external host to the controller 2002 and the semiconductor package 2003.

The controller 2002 may write data to or read data from the semiconductor package 2003, and may improve an operating speed of the electronic system 2000.

The DRAM 2004 may be a buffer memory for mitigating a speed difference between the semiconductor package 2003 as a data storage space and the external host. The DRAM 2004 included in the electronic system 2000 may also operate as a kind of cache memory, and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 disposed on a lower surface of each of the semiconductor chips 2200, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be a PCB including a plurality of package upper pads 2130. Each of the semiconductor chips 2200 may include an I/O pad 2201. The I/O pad 2201 may correspond to the I/O pad 1101 (refer to FIG. 13). Each of the semiconductor chips 2200 may include at least one of the IC devices 100, 200, and 300 described above with reference to FIGS. 4 to 11.

In some embodiments, the connection structure 2400 may be a bonding wire electrically connecting the I/O pad 2210 to the package upper pad 2130. Accordingly, in the first and second semiconductor packages 2003a and 2003b, the semiconductor chips 2200 may be electrically connected to each other by a bonding wire method, and may be electrically connected to the package upper pad 2130 of the package substrate 2100. In some embodiments, in the first and second semiconductor packages 2003a and 2003b, the semiconductor chips 2200 may be electrically connected to each other by a connection structure including a through-silicon via (TSV), instead of the bonding wire type connection structures 2400.

In some embodiments, the controller 2002 and the semiconductor chips 2200 may be included in a single package. In some embodiments, the controller 2002 and the semiconductor chips 2200 may be mounted on a separate interposer substrate different from the main board 2001, and the controller 2002 may be connected to the semiconductor chips 2200 by a wiring formed on the interposer substrate.

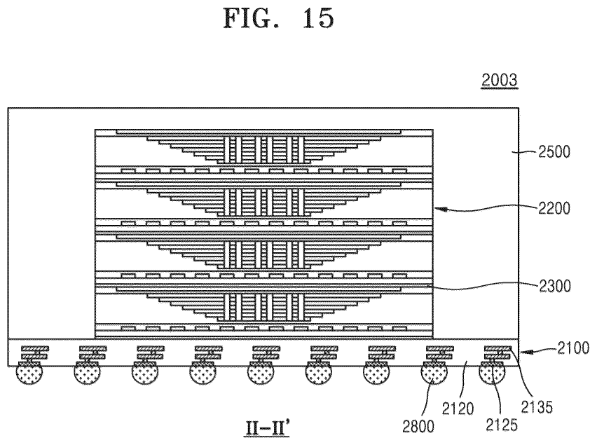

FIG. 15 is a cross-sectional view illustrating a semiconductor package 2003 including an IC device according to some embodiments.

Referring to FIG. 15, in the semiconductor package 2003, a package substrate 2100 may be a PCB.

The package substrate 2100 may include a body portion 2120, a package upper pad 2130 (refer to FIG. 14) disposed on an upper surface of the body portion 2120, a package lower pad 2125 (including a plurality of package lower pads) disposed on a lower surface of the body portion 2120 or exposed through the lower surface of the body portion 2120, and an internal wiring 2135 electrically connecting the package upper pad 2130 (refer to FIG. 14) to the package lower pad 2125 inside the body portion 2120.

The lower pads 2125 may be connected to the wiring patterns 2005 on the main board 2001 (refer to FIG. 14) through conductive bumps 2800, respectively. Each of the semiconductor chips 2200 may include at least one of the IC devices 100, 200, and 300 described above with reference to FIGS. 4 to 11.

While various embodiments been particularly shown and described with reference to the drawings showing the various embodiments, it will be understood that various changes in form and details may be made therein without departing from the spirit and scope of the following claims.

What is claimed is:

1. An integrated circuit (IC) device comprising:
a peripheral circuit structure and cell array structure,
wherein the peripheral circuit structure comprises:
a circuit substrate;
a peripheral circuit on the circuit substrate;
a first insulating layer covering the circuit substrate and the peripheral circuit; and
a first bonding pad disposed on the first insulating layer,
wherein the cell array structure comprises:
an insulating structure having a first surface and a second surface opposing the first surface;
a conductive plate on the first surface of the insulating structure;
a memory cell array on the conductive plate;
a second insulating layer covering the first surface of the insulating structure, the conductive plate, and the memory cell array;
a second bonding pad disposed on the second insulating layer;
a first wiring line and a second wiring line spaced apart from each other on the second surface of the insulating structure;
a conductive via passing through the insulating structure and connecting the conductive plate to the first wiring line; and
a contact structure electrically connecting the first wiring line to the second bonding pad, and
wherein the first bonding pad is in contact with the second bonding pad.

2. The IC device of claim 1, wherein, in plan view,
the first wiring line has a first length in a first horizontal direction and overlaps an edge of the conductive plate,
the second wiring line has a second length in the first horizontal direction and overlaps the conductive plate from one side of the second wiring line to another side of the second wiring line, and
the second length of the second wiring line is longer than the first length of the first wiring line.

3. The IC device of claim 2, wherein the second wiring line comprises a plurality of second wiring lines, and
in a plan view, the plurality of second wiring lines are respectively disposed on both sides of the first wiring line in a second horizontal direction perpendicular to the first horizontal direction.

4. The IC device of claim 2, wherein, in plan view,
a length of an overlap region in which the conductive plate overlaps the first wiring line in the first horizontal direction is about 5 μm or less, and
the conductive via is located only in the overlap region.

5. The IC device of claim 1, wherein the contact structure includes:
a first contact plug passing through the insulating structure; and
a second contact plug passing through the second insulating layer,
wherein the first contact plug is tapered and has a width narrowing in a vertical direction toward the circuit substrate, and
the second contact plug is tapered and has a width widening in the vertical direction toward the circuit substrate.

6. The IC device of claim 5, wherein a first height of the first contact plug in the vertical direction is less than a second height of the second contact plug in the vertical direction.

7. The IC device of claim 1, further comprising:
an input/output (I/O) pad located at an end of the second wiring line,
wherein a bonding wire is connected to the I/O pad to perform a power connection function and/or a ground connection function.

8. The IC device of claim 7, wherein a vertical level of the I/O pad is located at a same vertical level as a vertical level of each of the first wiring line and the second wiring line, or the vertical level of the I/O pad is located at a higher vertical level than the vertical level of each of the first wiring line and the second wiring line.

9. The IC device of claim 1, wherein:
the conductive plate corresponds to a common source line,
the peripheral circuit includes a common source line (CSL) driver, and
the common source line is electrically connected to the CSL driver by bypassing the first wiring line and the contact structure.

10. The IC device of claim 1, wherein the conductive plate includes a stack structure of a polysilicon layer, a barrier metal layer, and a metal layer.

11. An integrated circuit (IC) comprising:
a peripheral circuit structure including a circuit substrate, a peripheral circuit on the circuit substrate, a first insulating layer covering the peripheral circuit, and a first bonding pad disposed on the first insulating layer;
a first cell array structure including a first conductive plate, a first memory cell array below the first conductive plate, a second insulating layer covering the first memory cell array, a second bonding pad below the second insulating layer, a first conductive via on the first conductive plate, a third bonding pad connected to the first conductive via, and a first contact structure passing through the second insulating layer to connect the second bonding pad to the third bonding pad; and
a second cell array structure including a second conductive plate, a second memory cell array below the second conductive plate, a third insulating layer covering the second memory cell array, a fourth bonding pad below the third insulating layer, a second conductive via on the second conductive plate, a first wiring line connected to the second conductive via, and a second contact structure passing through the third insulating layer to connect the fourth bonding pad to the first wiring line,
wherein the first bonding pad is in contact with the second bonding pad, and
wherein the third bonding pad is in contact with the fourth bonding pad.

12. The IC device of claim 11, wherein the fourth bonding pad comprises a plurality of fourth bonding pads, and
the IC device further comprises:
an extended wiring line disposed in the third insulating layer of the second cell array structure and electrically connecting the plurality of fourth bonding pads,
wherein the first conductive plate of the first cell array structure is electrically connected to the first contact structure a through the extended wiring line.

13. The IC device of claim 11, wherein, in a plan view,
the first wiring line has an overlap region overlapping an edge of the second conductive plate in a first horizontal direction, and
the second conductive via is disposed only in the overlap region.

14. The IC device of claim 13, further comprising:
a second wiring line disposed on the same vertical level as a vertical level of the first wiring line,
wherein the second wiring line overlaps the second conductive plate from one side of the second wiring line to another side of the second wiring line in the first horizontal direction.

15. The IC device of claim 12, wherein:
the first conductive plate and the second conductive plate correspond to a common source line,
the peripheral circuit includes a common source line (CSL) driver,
the first conductive plate is electrically connected to the CSL driver by bypassing the extended wiring line and the first contact structure, and
the second conductive plate is electrically connected to the CSL driver by bypassing the first wiring line and the second contact structure.

16. An integrated circuit (IC) comprising:
a peripheral circuit structure including a circuit substrate, a peripheral circuit on the circuit substrate, a first insulating layer covering the peripheral circuit, and a first bonding pad disposed on the first insulating layer;
a first cell array structure including a first conductive plate, a first memory cell array below the first conductive plate, a second insulating layer covering the first memory cell array, a second bonding pad below the second insulating layer, a first conductive via on the first conductive plate, a third bonding pad connected to the first conductive via, and a first contact structure passing through the second insulating layer to connect the second bonding pad to the first conductive plate; and
a second cell array structure including a second conductive plate, a second memory cell array below the second conductive plate, a third insulating layer covering the second memory cell array, a fourth bonding pad below the third insulating layer, and a second contact structure passing through the third insulating layer to connect the fourth bonding pad to the second conductive plate,
wherein the first bonding pad is in contact with the second bonding pad, and
wherein the third bonding pad is in contact with the fourth bonding pad.

17. The IC device of claim 16, wherein the first bonding pad, the second bonding pad, the third bonding pad, and the fourth bonding pad and the first contact structure and the second contact structure are electrically connected to each other and are all aligned in a vertical direction.

18. The IC device of claim 17, wherein:
the first contact structure is located outside the first memory cell array, and
the second contact structure is located outside the second memory cell array.

19. The IC device of claim 16, wherein:
the first conductive via is tapered and has a width narrowing in a vertical direction toward the circuit substrate, and
each of the first contact structure and the second contact structure is tapered and has a width widening in the vertical direction toward the circuit substrate.

20. The IC device of claim 16, wherein:
the first conductive plate and the second conductive plate correspond to a common source line,
the peripheral circuit includes a common source line (CSL) driver,
the first conductive plate is electrically connected to the CSL driver through the first contact structure, and
the second conductive plate is electrically connected to the CSL driver through the first contact structure and the second contact structure.
